(19) United States
(12) Patent Application Publication
(10) Pub. No.: US 2010/0327919 A1
(43) Pub. Date: Dec. 30, 2010

(54) DIFFERENTIAL AMPLIFIER CIRCUIT

(75) Inventor: Yutaka Oka, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI SEMICONDUCTOR CO., LTD., Tokyo (JP)

(21) Appl. No.: 12/823,248

(22) Filed: Jun. 25, 2010

(30) Foreign Application Priority Data
Jun. 30, 2009 (JP) 2009-155480

(51) Int. Cl. H03K 3/00; H03F 3/45

(52) U.S. Cl. 327/109; 330/261

(57) ABSTRACT

A differential amplifier main circuit amplifies, while first voltage is applied to drains of first and second transistors via a load circuit and second voltage is applied to source of third transistor, a difference between voltages applied to gates of the first and second transistors, and outputs it from a connection between the load circuit and drains of the first or second transistor. A voltage application circuit applies voltage to the gate of the third transistor so that a current between the source and drain thereof to have a predetermined magnitude. Gates of transistors of the application circuit are connected to a second common-connection of drains thereof to which the first voltage is applied via a load, the second voltage is applied to a first common-connection of sources of the transistors, and a connection of the second common-connection and the load is connected to the gate of the third transistor.

### CROSS-REFERENCE TO RELATED APPLICATION

This application claims priority under 35 USC 119 from Japanese Patent Application No. 2009-155480 filed on Jun. 30, 2009, the disclosure of which is incorporated by reference herein.

### BACKGROUND

1. Field of the Invention

The present invention relates to a differential amplifier circuit, and in particular, to a differential amplifier circuit having a voltage application circuit that applies, to a differential amplifier circuit, voltage for controlling the magnitude of current flowing to the differential amplifier circuit.

2. Related Art

A differential amplifier circuit 20A shown in FIG. 3 is known as a conventional differential amplifier circuit (see, for example, Japanese Patent Application Laid-Open (JP-A) No. 11-27138). Note that, in the following description, an “N channel type MOS transistor” is called an “NMOS transistor”, and a “P channel type MOS transistor” is called a “PMOS transistor”.

As shown in FIG. 3, the differential amplifier circuit 20A is structured to include a differential amplifier main circuit 30A and a voltage application circuit 40A. The differential amplifier main circuit 30A is structured from an NMOS transistor Q10 whose source terminal is grounded, NMOS transistors Q11 and Q12 whose respective source terminals are connected to the drain terminal of the NMOS transistor Q10, and PMOS transistors Q15 and Q16 whose source terminals are respectively connected to driving voltage V_{cc}.

Voltage V_{ref0}, whose level does not vary even if the driving voltage V_{cc} varies, is applied to the gate terminal of the NMOS transistor Q10 from the voltage application circuit 40A. Voltage V_{ref} is applied to the gate terminal of the NMOS transistor Q11, and voltage Vᵢₙ is applied to the gate terminal of the NMOS transistor Q12. The drain terminal and the gate terminal of the PMOS transistor Q15 are connected to the drain terminal of the NMOS transistor Q11. The drain terminal of the PMOS transistor Q16 is connected to the drain terminal of the NMOS transistor Q12. The gate terminals of the PMOS transistors Q15 and Q16 are connected to one another.

In the differential amplifier main circuit 30A that is structured in this way, voltage Vₒᵤₜ is outputted from connection point A of the common drain of the CMOS transistor formed from the NMOS transistor Q12 and the PMOS transistor Q16.

A circuit diagram of the voltage application circuit 40A is shown in FIG. 4. As shown in FIG. 4, the voltage application circuit 40A has: a PMOS transistor Q30 whose source voltage is the driving voltage V_{cc} and whose gate voltage is GND level; a PMOS transistor Q40 whose drain terminal and gate terminal are grounded, and whose substrate is connected to the source terminal, and whose threshold voltage is Vₜₚ₁; and a PMOS transistor Q50 whose drain terminal is connected to the gate terminal and a constant current source 50, and whose substrate is connected to the source terminal, and whose threshold voltage is Vₜₚ₂. Further, connection point B of the PMOS transistor Q50 and the constant current source 50 is connected to the input terminal of a differential amplifier circuit section 60. The voltage application circuit 40A also has a PMOS transistor Q60 whose gate terminal is connected to the output terminal of the differential amplifier circuit section 60, and whose source voltage is the driving voltage V_{cc}, and that outputs voltage V_{ref0} from the drain terminal. The drain terminal of the PMOS transistor Q30 is connected to the respective source terminals of the PMOS transistors Q40 and Q50.

At the voltage application circuit 40A that is structured in this way, even if the driving voltage V_{cc} varies, difference voltage |Vₜₚ₁−Vₜₚ₂| of the respective threshold voltages of the PMOS transistors Q40 and Q50 is amplified at the differential amplifier circuit section 60, and thereafter, by applying the amplified difference voltage to the gate terminal of the PMOS transistor Q60, the voltage V_{ref0} that is smaller than the driving voltage V_{cc} and larger than the voltages V_{ref} and Vᵢₙ, is generated from the drain terminal of the PMOS transistor Q60.

Further, a voltage application circuit 40B shown in FIG. 5 is known as an example of another conventional voltage application circuit. As shown in FIG. 5, the voltage application circuit 40B is structured to include a PMOS transistor Q70 and an NMOS transistor Q80. The PMOS transistor Q70 and the NMOS transistor Q80 are connected in series. The driving voltage V_{cc} is applied to the source terminal of the PMOS transistor Q70, and the source terminal of the NMOS transistor Q80 is grounded. Further, at each of the PMOS transistor Q70 and the NMOS transistor Q80, the gate terminal is connected to the drain terminal thereof. A connection point D of the transistor Q70 and the transistor Q80 is connected to the NMOS transistor Q10.

The magnitude of the current that flows through the NMOS transistor Q11 and the PMOS transistor Q15, and the magnitude of the current that flows through the NMOS transistor Q12 and the PMOS transistor Q16, are controlled by the voltage that is applied to the gate terminal of the NMOS transistor Q10 by the voltage application circuit 40B.

Moreover, a voltage application circuit 40C shown in FIG. 6 is known as an example of yet another conventional voltage application circuit. As shown in FIG. 6, the voltage application circuit 40C differs from the voltage application circuit 40B shown in FIG. 5 only with regard to the point that, in the voltage application circuit 40C, a resistor R₀ is disposed between the connection point D and the drain terminal of the PMOS transistor Q70. Therefore, as compared with the voltage application circuit 40B shown in FIG. 5, in the voltage application circuit 40C, the magnitude of the voltage that is applied to the gate terminal of the NMOS transistor Q10 from the connection point D is lowered.

If the external power supply voltage, that is supplied to an electronic device having the differential amplifier circuit 20A shown in FIG. 3, becomes larger due to, for example, operation of the user, accompanying this, the driving voltage V_{cc} also rises. However, in the differential amplifier circuit 20A shown in FIG. 3, the differential amplifier main circuit 30A can be operated at a substantially constant consumed current, regardless of a rise in the driving voltage V_{cc}.

However, in the differential amplifier circuit 20A shown in FIG. 3, the circuit scale of the voltage application circuit 40A is large as shown in FIG. 4.

If the voltage application circuit 40B shown in FIG. 5 is used instead of the voltage application circuit 40A, the circuit scale may be smaller than the voltage application circuit 40A, but the consumed current at the differential amplifier main circuit 30A also increases accompanying a rise in the driving voltage V_{cc}.

If the voltage application circuit 40C shown in FIG. 6 is used instead of the voltage application circuit 40B, the increase in consumed current that accompanies a rise in the driving voltage V_{cc} at the differential amplifier main circuit 30A is kept smaller than in a case in which the voltage application circuit 40B is used. However, accompanying a drop in the driving voltage V_{cc}, the voltage that is applied to the differential amplifier main circuit 30A becomes insufficient. Therefore, not only does the amplifying ability at the differential amplifier main circuit 30A deteriorate, but also, the speed of application of voltage to the differential amplifier main circuit 30A immediately after the power supply is turned on becomes slow.

### SUMMARY

The present invention provides a differential amplifier circuit that, while suppressing enlargement of the circuit scale, suppresses an increase in consumed current that accompanies a rise in driving voltage, and can eliminate an insufficiency of applied voltage that accompanies a drop in the driving voltage.

An aspect of the present invention is a differential amplifier circuit including: a differential amplifier main circuit having first through third transistors of a predetermined electrically-conductive type that respectively have a first terminal, a second terminal and a control terminal, wherein the first terminal of the second transistor is connected to the first terminal of the first transistor, the second terminal of the third transistor is connected to the respective first terminals of the first and second transistors, and, in a state in which a first driving voltage is applied to the respective second terminals of the first and second transistors via a predetermined load circuit and a second driving voltage that is lower than the first driving voltage is applied to the first terminal of the third transistor, when voltages are applied to the respective control terminals of the first and second transistors, the differential amplifier main circuit amplifies a difference between the voltages applied to the respective control terminals of the first and second transistors, and outputs the amplified difference voltage from a connection point between the load circuit and the second terminal of the first transistor or the second terminal of the second transistor; and a voltage application circuit that applies voltage, that makes a magnitude of a current flowing between the first terminal and the second terminal of the third transistor to have a predetermined magnitude, to the control terminal of the third transistor, the voltage application circuit having plural transistors of a predetermined electrically-conductive type having different threshold voltages that are connected in parallel, each of the plural transistors having a first terminal, a second terminal, and a control terminal, wherein the respective control terminals of the plural transistors are connected to a second common connection point of the respective second terminals of the plural transistors, the first driving voltage is applied via a load to the second common connection point, the second driving voltage is applied to a first common connection point of the respective first terminals of the plural transistors, and a connection point of the second common connection point and the load is connected to the control terminal of the third transistor.

In accordance with the above-described aspect, the number of transistors that are in a conducting state of the plural transistors of the predetermined electrically-conductive type that are connected in parallel, varies accompanying fluctuations in the first driving voltage. Due thereto, the voltage that is applied, as voltage applied to the control terminal of the third transistor, between the common connection point of the respective first terminals of the plural transistors of the predetermined electrically-conductive type and the common connection point of the respective second terminals of the plural transistors of the predetermined electrically-conductive type, is adjusted such that the magnitude of the current flowing between the first terminal and the second terminal of the third transistor is a predetermined magnitude. Therefore, while enlargement of the circuit scale is suppressed, an increase in consumed current that accompanies a rise in the driving voltage is suppressed, and an insufficiency in applied voltage that accompanies a drop in the driving voltage can be eliminated.

In the above-described aspect, the load circuit may be a current mirror circuit that includes fourth and fifth transistors that respectively have a first terminal, a second terminal and a control terminal, and that are of an electrically-conductive type that is different than the electrically-conductive type of the first transistor.

In the above-described aspect, the load may be a sixth transistor that has a first terminal, a second terminal and a control terminal and that is of an electrically-conductive type that is different than the electrically-conductive type of the first transistor, the first driving voltage may be applied to the first terminal of the sixth transistor, the control terminal of the sixth transistor may be connected to the second terminal of the sixth transistor, and the second terminal of the sixth transistor may be connected to the second common connection point of the respective second terminals of the plural of transistors of the electrically-conductive type.

In the above-described aspect, the first terminals may be source terminals, the second terminals may be drain terminals, and the control terminals may be gate terminals.

In accordance with the above-described aspects, while enlargement of the circuit scale is suppressed, an increase in consumed current that accompanies a rise in the driving voltage is suppressed, and an insufficiency in applied voltage that accompanies a drop in the driving voltage can be eliminated.

### BRIEF DESCRIPTION OF THE DRAWINGS

An exemplary embodiment of the present invention will be described in detail based on the following figures, wherein:

FIG. 1 is a circuit drawing showing the structure of a differential amplifier circuit relating to an exemplary embodiment;

FIG. 2 is a graph showing an example of the relationship between consumed current and driving voltage of a differential amplifier main circuit that is included in the differential amplifier circuit relating to the exemplary embodiment, and examples of the relationships between consumed current and driving voltage of a differential amplifier main circuit that is included in conventional differential amplifier circuits;

FIG. 3 is a circuit drawing (a partial block drawing) showing the structure of a conventional differential amplifier circuit;

FIG. 4 is a circuit drawing (a partial block drawing) showing the structure of a voltage application circuit that is included in the conventional differential amplifier circuit;

FIG. 5 is a circuit drawing showing the structure of a conventional differential amplifier circuit; and

FIG. 6 is a circuit drawing showing the structure of a conventional differential amplifier circuit.

### DETAILED DESCRIPTION

An exemplary embodiment is described in detail hereinafter with reference to the drawings.

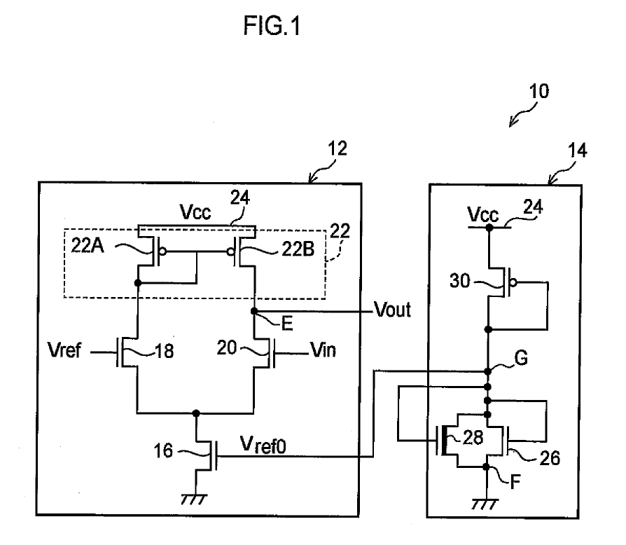

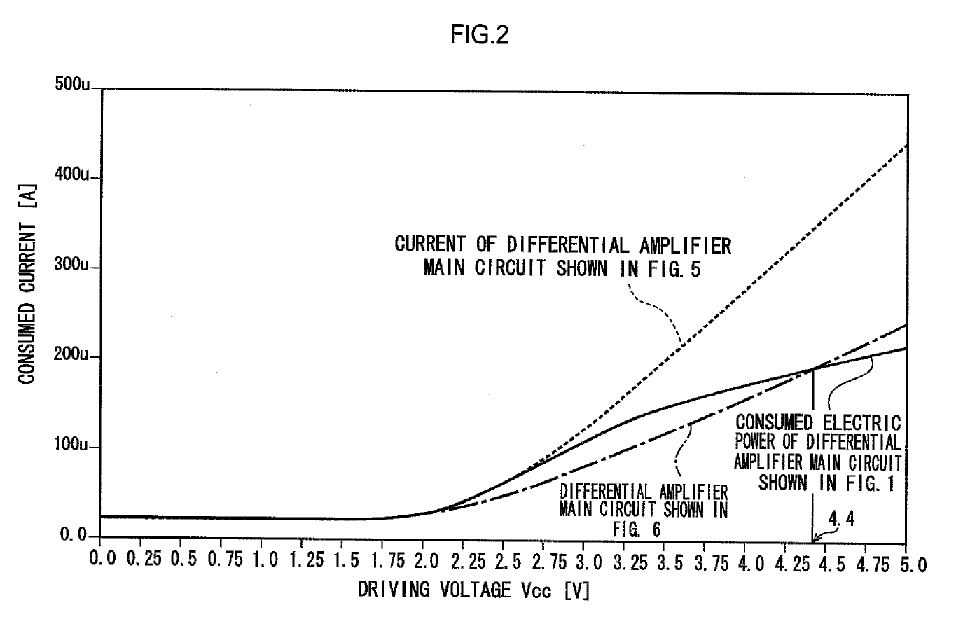

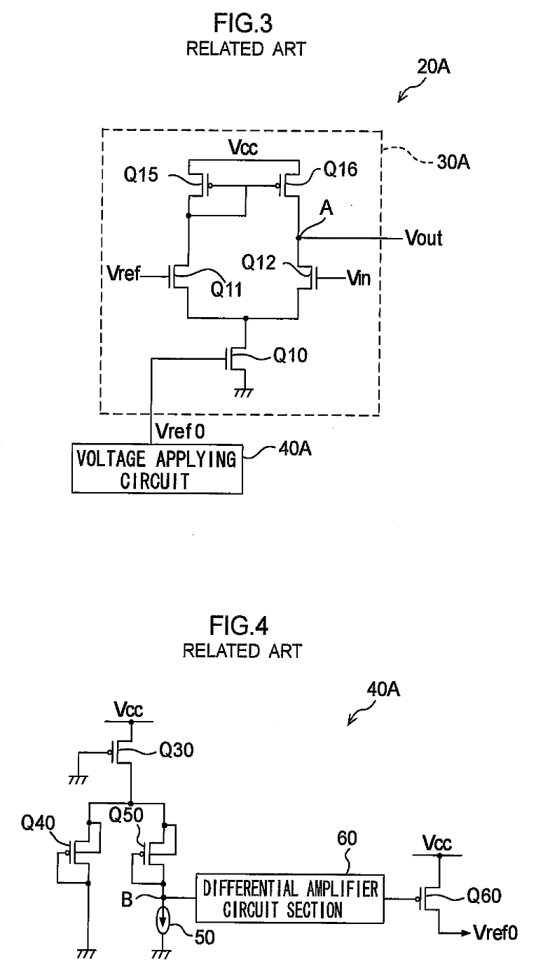

FIG. 1 is a circuit drawing showing the structure of a differential amplifier circuit 10 relating to the present exemplary embodiment. As shown in FIG. 1, the differential amplifier circuit 10 includes a differential amplifier main circuit 12 and a voltage application circuit 14.

The differential amplifier main circuit 12 includes NMOS transistors 16, 18, and 20 having source terminals serving as first terminals, drain terminals serving as second terminals, and gate terminals serving as control terminals, and a current mirror circuit 22. The source terminal of the NMOS transistor 16 that serves as a third transistor is grounded. Accordingly, voltage, that is GND level and that serves as second driving voltage, is applied to the source terminal of the NMOS transistor 16. Further, the drain terminal of the NMOS transistor 16 is connected to the respective source terminals of the NMOS transistor 18 serving as a first transistor and the NMOS transistor 20 serving as a second transistor. The gate terminal, that serves as a control terminal, of the NMOS transistor 16 is connected to the voltage application circuit 14, and V_{ref0} is applied to the gate terminal of the NMOS transistor 16 from the voltage application circuit 14.

The current mirror circuit 22 includes PMOS transistors 22A and 22B having source terminals serving as first terminals, drain terminals serving as second terminals, and gate terminals serving as control terminals. The respective source terminals of the PMOS transistors 22A and 22B are connected to a voltage line 24. Driving voltage V_{cc}, that serves as a first driving voltage and that is higher than GND level voltage, is applied to the voltage line 24. Therefore, the driving voltage V_{cc} is applied to the respective source terminals of the PMOS transistors 22A and 22B.

The gate terminal and the drain terminal of the PMOS transistor 22A, that serves as a fourth transistor, are connected to the drain terminal of the NMOS transistor 18. The gate terminal of the PMOS transistor 22B, that serves as a fifth transistor, is connected to the gate terminal of the PMOS transistor 22A. The drain terminal of the PMOS transistor 22B is connected to the drain terminal of the NMOS transistor 20.

Voltage V_{ref} is applied to the gate terminal of the NMOS transistor 18, and voltage Vᵢₙ is applied to the gate terminal of the NMOS transistor 20.

A connection point E of the common drain of a CMOS transistor, that is formed from the NMOS transistor 20 and the PMOS transistor 22B, is connected to an external circuit (not shown).

The voltage application circuit 14 includes NMOS transistors 26 and 28 having source terminals serving as first terminals, drain terminals serving as second terminals, and gate terminals serving as control terminals, and a PMOS transistor 30 having a source terminal serving as a first terminal, a drain terminal serving as a second terminal, and a gate terminal serving as a control terminal.

The NMOS transistor 28 is connected in parallel to the NMOS transistor 26. Namely, the drain terminal of the NMOS transistor 26 is connected to the drain terminal of the NMOS transistor 28, and the source terminal of the NMOS transistor 26 is connected to the source terminal of the NMOS transistor 28.

Threshold voltage α when the NMOS transistor 26 is on (in a conducting state) and threshold voltage β when the NMOS transistor 28 is on are different. With regard to the respective gate widths of the NMOS transistors 26 and 28, impurities are implanted into the source-drain regions such that α<<β. Ion injection is an example of the method of implantation. P+, As+, and the like are examples of the impurities. Note that the present invention is not limited to the same, and the gate widths of the NMOS transistors 26, 28 may be adjusted such that α<<β.

A common connection point F of the respective source terminals of the NMOS transistors 26 and 28 is grounded. The respective gate terminals and drain terminals of the NMOS transistors 26 and 28 are connected to the drain terminal of the PMOS transistor 30 that serves as a sixth transistor.

The source terminal of the PMOS transistor 30 is connected to the voltage line 24. The gate terminal of the PMOS transistor 30 is connected to the drain terminal thereof.

A connection point G of the common drain of the NMOS transistors 26 and 28 and the PMOS transistor 30 is connected to the gate terminal of the NMOS transistor 16 of the differential amplifier main circuit 12.

Voltage of a predetermined voltage range (e.g., greater than or equal to 0 V to less than or equal to 5.0 V) can be applied as the driving voltage V_{cc} to the voltage line 24 of the differential amplifier circuit 10. The magnitudes of the threshold voltage α of the NMOS transistor 26, the threshold voltage β of the NMOS transistor 28, and the load of the PMOS transistor 30 are set such that, when the driving voltage V_{cc} fluctuates within the aforementioned predetermined voltage range, the voltage V_{ref0}, that makes the magnitude of the current flowing to the drain terminal and the source terminal of the NMOS transistor 16 be a predetermined current magnitude, is applied from the voltage application circuit 14 to the gate terminal of the NMOS transistor 16.

Circuit operation of the differential amplifier circuit 10 is described next.

When, in the state in which the driving voltage V_{cc} within the aforementioned predetermined voltage range is applied to the voltage line 24, voltage is applied to the respective gate terminals of the NMOS transistors 18 and 20, the voltage Vₒᵤₜ, that is obtained by amplifying the voltage corresponding to the difference of the voltages applied to the respective gate terminals of the NMOS transistors 18 and 20, is outputted to an external circuit from the connection point E of the differential amplifier main circuit 12.

For example, when the driving voltage V_{cc} that is greater than or equal to 0 V and less than 4.4 V is applied to the voltage line 24, at the voltage application circuit 14, the PMOS transistor 30 and the NMOS transistor 26 enter into conducting states, and the NMOS transistor 28 enters into a shut-off state, and, between the connection point G and the common connection point F, the voltage that is applied to the NMOS transistor 26 is the voltage V_{ref0} that is applied to the gate terminal of the NMOS transistor 16 from the connection point G.

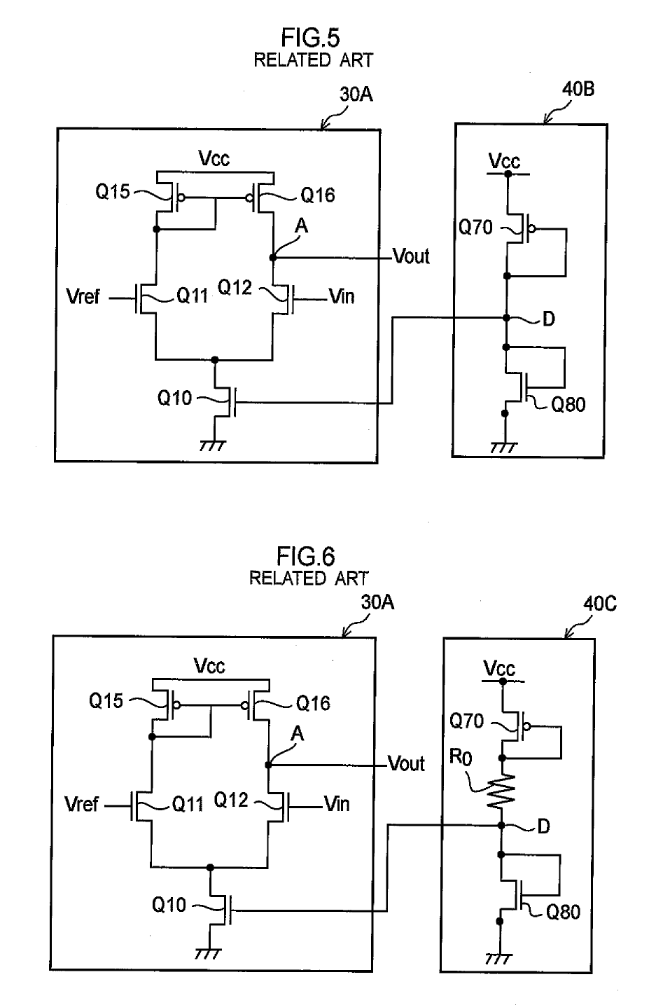

The magnitude of the current that flows to the drain terminal and the source terminal of the NMOS transistor 16 when the driving voltage V_{cc} that is greater than or equal to 0 V and less than 4.4 V is applied to the voltage line 24, i.e., the magnitude of the consumed current of the differential amplifier main circuit 12, is, as shown as an example in FIG. 2, substantially the same as the magnitude of the consumed current of the differential amplifier main circuit 30A shown in FIG. 5 and FIG. 6 when the driving voltage V_{cc} is greater than or equal to 0 V and less than 2.0 V. When the driving voltage V_{cc} is greater than or equal to 2.0 V and less than 4.4 V, the magnitude of the consumed current of the differential amplifier main circuit 12 is lower than the magnitude of the consumed current of the differential amplifier main circuit 30A shown in FIG. 5, and is greater than the consumed current of the differential amplifier main circuit 30A shown in FIG. 6.

Further, when the driving voltage V_{cc} that is greater than or equal to 4.4 V and less than or equal to 5.0 V is applied to the voltage line 24 for example, the PMOS transistor 30 and the NMOS transistors 26 and 28 enter into conducting states, and between the connection point G and the common connection point F, the voltage that is applied to the parallel circuit formed from the NMOS transistors 26 and 28 is the voltage V_{ref0} that is applied from the connection point G to the gate terminal of the NMOS transistor 16.

The magnitude of the current, that flows to the drain terminal and the source terminal of the NMOS transistor 16 when the driving voltage V_{cc} that is greater than or equal to 4.4 V and less than or equal to 5.0 V is applied to the voltage line 24, is, as shown as an example in FIG. 2, lower than the magnitudes of the consumed currents of the differential amplifier main circuit 30A shown in FIG. 5 and FIG. 6.

FIG. 2 is a graph showing an example of the relationship between the consumed current and the driving voltage V_{cc} at the differential amplifier main circuit 12 relating to the present exemplary embodiment, and an example of the relationship between the consumed current and the driving voltage V_{cc} at the conventional differential amplifier main circuit 30A shown in FIG. 5, and an example of the relationship between the consumed current and the driving voltage V_{cc} at the conventional differential amplifier main circuit 30A shown in FIG. 6.

As described above, the differential amplifier circuit 10 relating to the present exemplary embodiment can suppress an increase in the consumed current that accompanies a rise in the driving voltage V_{cc} by the voltage application circuit 14 whose circuit scale is smaller than the conventional voltage application circuit 40A shown in FIG. 4. Further, the differential amplifier circuit 10 relating to the present exemplary embodiment can suppress an increase in consumed current that accompanies a rise in the driving voltage V_{cc}, as compared with the conventional differential amplifier circuit shown in FIG. 5. Moreover, the differential amplifier circuit 10 relating to the present exemplary embodiment can eliminate an insufficiency of applied voltage that is applied by the voltage application circuit 40C to the differential amplifier main circuit 12 at the time when the driving voltage V_{cc} (here, greater than or equal to 2.0 V and less than 4.4 V for example), at which an insufficiency in applied voltage that is applied by the voltage application circuit 40C to the conventional differential amplifier main circuit 30A shown in FIG. 6 markedly appears, is applied to the voltage line 24, and further, can suppress an increase in consumed current that accompanies a rise in the driving voltage V_{cc}.

As described in detail above, in accordance with the differential amplifier circuit 10 relating to the present exemplary embodiment, in the state in which the driving voltage V_{cc} is applied to the voltage line 24, when the voltage V_{ref} is applied to the gate terminal of the NMOS transistor 18 and the voltage Vᵢₙ is applied to the gate terminal of the NMOS transistor 20 respectively, the voltage Vₒᵤₜ, that amplifies the voltage corresponding to the difference in the voltages that are applied to the respective gate terminals of the NMOS transistors 18 and 20, is outputted to an external circuit from the connection point E of the differential amplifier main circuit 12. On the other hand, as the driving voltage V_{cc} fluctuates, the number of NMOS transistors that are in a conducting state at the NMOS transistors 26 and 28 that are connected in parallel changes. Due thereto, the voltage, that is applied between the common connection point F of the respective source terminals of the NMOS transistors 26 and 28 and the connection point G of the common drain of the NMOS transistors 26 and 28 and the PMOS transistor 30, as the voltage that is applied to the gate terminal of the NMOS transistor 16, is adjusted such that the magnitude of the current flowing between the source terminal and the drain terminal of the NMOS transistor 16 is made to be a predetermined magnitude (in the present exemplary embodiment, the consumed current of the solid line graph in FIG. 2). Therefore, while enlarging of the circuit scale is suppressed, an increase in consumed current that accompanies a rise in the driving voltage is suppressed, and an insufficiency of applied voltage that accompanies a drop in the driving voltage can be eliminated.

In accordance with the differential amplifier circuit 10 relating to the present exemplary embodiment, the differential amplifier main circuit 12 has the current mirror circuit 22 that is structured by the PMOS transistors 22A and 22B. Due to the driving voltage V_{cc} being applied to the respective drain terminals of the NMOS transistors 18 and 20 via the current mirror circuit 22, the current amount that is supplied to the drain terminal of the NMOS transistor 18 and the current amount that is supplied to the drain terminal of the NMOS transistor 20 is substantially equal. Therefore, the reliability of the voltage Vₒᵤₜ that is obtained by the differential amplifier main circuit 12 can be improved.

Further, in accordance with the differential amplifier circuit 10 relating to the present exemplary embodiment, due to the driving voltage V_{cc} being applied to the common connection point of the respective drain terminals of the NMOS transistors 26 and 28 via the PMOS transistor 30, the PMOS transistor 30 functions as a load that corresponds to the magnitude of the driving voltage V_{cc}. Therefore, the voltage V_{ref0} that is applied to the gate terminal of the NMOS transistor 16 can easily be adjusted.

The above exemplary embodiment describes, as an example, the voltage application circuit 14 that has the parallel circuit that is structured by two NMOS transistors being connected in parallel. However, embodiments are not limited to the same, and a voltage application circuit, that has a parallel circuit structured by three or more NMOS transistors whose threshold voltages are different being connected in parallel, may be used. In this case, the adjustment of the voltage V_{ref0} accompanying the fluctuations in the driving voltage V_{cc} can be carried out even more finely.

The above exemplary embodiment describes, as an example, the differential amplifier main circuit 12 that has the current mirror circuit 22, but embodiments are not limited to the same. Instead of the PMOS transistors 22A and 22B that structure the current mirror circuit 22, a pair of loads (e.g. a pair of resistors), that do not adversely affect the function of the differential amplifier main circuit 12 amplifying and outputting the difference of the voltages applied to the respective gate terminals of the NMOS transistors 18 and 20, may be used.

The voltage application circuit 14 that has the PMOS transistor 30 is described as an example in the above exemplary embodiment. However, embodiments are not limited to the same. Instead of the PMOS transistor 30, a load (e.g., a resistor) that can apply, from the voltage application circuit 14 to the gate terminal of the NMOS transistor 16, the voltage V_{ref0} that makes the magnitude of the current flowing to the drain terminal and the source terminal of the NMOS transistor 16 be a predetermined magnitude, may be used.

Although the present exemplary embodiment describes, as an example, a case of using field effect transistors at the differential amplifier main circuit 12, embodiments are not limited to the same, and bipolar transistors may be used at the differential amplifier main circuit 12. In this case, bipolar transistors may be assembled into the differential amplifier main circuit 12 instead of field effect transistors, such that the collector terminals of the bipolar transistors correspond to the drain terminals of the field effect transistors, and the emitter terminals of the bipolar transistors corresponds to the source terminals of the field effect transistors, and the base terminals of the bipolar transistors corresponds to the gate terminals of the field effect transistors.

What is claimed is:

1. A differential amplifier circuit comprising:
a differential amplifier main circuit comprising first through third transistors of a predetermined electrically-conductive type that respectively have a first terminal, a second terminal and a control terminal, wherein the first terminal of the second transistor is connected to the first terminal of the first transistor, the second terminal of the third transistor is connected to the respective first terminals of the first and second transistors, and, in a state in which a first driving voltage is applied to the respective second terminals of the first and second transistors via a predetermined load circuit and a second driving voltage that is lower than the first driving voltage is applied to the first terminal of the third transistor, when voltages are applied to the respective control terminals of the first and second transistors, the differential amplifier main circuit amplifies a difference between the voltages applied to the respective control terminals of the first and second transistors, and outputs the amplified difference voltage from a connection point between the load circuit and the second terminal of the first transistor or the second terminal of the second transistor; and
a voltage application circuit that applies voltage, that makes a magnitude of a current flowing between the first terminal and the second terminal of the third transistor to have a predetermined magnitude, to the control terminal of the third transistor, the voltage application circuit comprising a plurality of transistors of a predetermined electrically-conductive type having different threshold voltages that are connected in parallel, each of the plurality of transistors having a first terminal, a second terminal, and a control terminal, wherein the respective control terminals of the plurality of transistors are connected to a second common connection point of the respective second terminals of the plurality of transistors, the first driving voltage is applied via a load to the second common connection point, the second driving voltage is applied to a first common connection point of the respective first terminals of the plurality of transistors, and a connection point of the second common connection point and the load is connected to the control terminal of the third transistor.

2. The differential amplifier circuit of claim 1, wherein the load circuit is a current mirror circuit that includes fourth and fifth transistors that respectively have a first terminal, a second terminal and a control terminal, and that are of an electrically-conductive type that is different than the electrically-conductive type of the first transistor.

3. The differential amplifier circuit of claim 1, wherein the load is a sixth transistor that has a first terminal, a second terminal and a control terminal and that is of an electrically-conductive type that is different than the electrically-conductive type of the first transistor, the first driving voltage is applied to the first terminal of the sixth transistor, the control terminal of the sixth transistor is connected to the second terminal of the sixth transistor, and the second terminal of the sixth transistor is connected to the second common connection point of the respective second terminals of the plurality of transistors.

4. The differential amplifier circuit of claim 1, wherein the first terminals are source terminals, the second terminals are drain terminals, and the control terminals are gate terminals.
